(19) United States
(12) Patent Application Publication
(10) Pub. No.: US 2012/0246545 A1
(43) Pub. Date: Sep. 27, 2012

(54) METHOD FOR ENHANCING DATA PROTECTION PERFORMANCE, AND ASSOCIATED PERSONAL COMPUTER AND STORAGE MEDIUM

(76) Inventors: Wen-Po Lin, Hsinchu City (TW); Hsu-Ping Ou, Hsinchu County (TW)

(21) Appl. No.: 13/298,298

(22) Filed: Nov. 17, 2011

(30) Foreign Application Priority Data
Mar. 25, 2011 (TW) 100110305

(51) Int. Cl. H03M 13/05; G06F 11/10

(52) U.S. Cl. 714/773; 714/E11.032

(57) ABSTRACT

A method for enhancing data protection performance is provided. The method is applied to a personal computer that includes/is electronically connected to a memory device, and the memory device includes a Flash memory. The method includes: with regard to data to be written/programmed into the Flash memory of the memory device by the personal computer, generating at least one Error Correction Code (ECC) corresponding to the data, and storing the ECC into a file within the personal computer, wherein the file is stored in a storage of the personal computer; and when it is detected that an uncorrectable error of at least one portion of the data stored in the Flash memory occurs, performing error correction according to the ECC stored in the file, in order to correct the data stored in the Flash memory. An associated personal computer and a storage medium storing an associated driver are further provided.

### BACKGROUND OF THE INVENTION

1. Field of the Invention

The present invention relates to access to a Flash memory, and more particularly, to a method for enhancing data protection performance, and to an associated personal computer and a storage medium storing an associated driver.

2. Description of the Prior Art

As technologies of Flash memories progress in recent years, many kinds of portable memory devices (e.g. memory cards respectively complying with SD/MMC, CF, MS, and XD standards) or solid state drives (SSDs) equipped with Flash memories are widely implemented in various applications. Therefore, the control of access to Flash memories in these memory devices has become an important issue.

Taking NAND Flash memories as an example, they can mainly be divided into two types, i.e. Single Level Cell (SLC) Flash memories and Multiple Level Cell (MLC) Flash memories. Each transistor that is considered a memory cell in SLC Flash memories only has two charge levels that respectively represent a logical value 0 and a logical value 1. In addition, the storage capability of each transistor that is considered a memory cell in MLC Flash memories can be fully utilized. More specifically, the voltage for driving memory cells in the MLC Flash memories is typically higher than that in the SLC Flash memories, and different voltage levels can be applied to the memory cells in the MLC Flash memories in order to record information of at least two bits (e.g. binary values 00, 01, 11, or 10) in a transistor that is considered a memory cell. Theoretically, the storage density of the MLC Flash memories may reach twice the storage density of the SLC Flash memories, which is considered good news for NAND Flash memory manufacturers who encountered a bottleneck of NAND Flash technologies.

As MLC Flash memories are cheaper than SLC Flash memories, and are capable of providing higher capacity than SLC Flash memories while the space is limited, MLC Flash memories have been a main stream for implementation of most portable memory devices on the market. However, various problems of the MLC Flash memories have arisen due to their unstable characteristics. In order to ensure that the access control of a memory device over the Flash memory therein can comply with related standards, the controller of the Flash memory should have some handling mechanisms in order to properly handle its data access operations.

According to the related art, the memory device having the aforementioned handling mechanisms may still suffer from some deficiencies. For example, the handling mechanisms of the related art cannot arbitrarily increase the basic error correction bit count (which typically represents the error correction capability measured in bits with respect to a specific amount of data) of an Error Correction Code (ECC) engine. In addition, once the basic error correction bit count of the ECC engine is increased, the associated costs of the ECC engine are greatly increased. For example, with respect to 1 K bytes (i.e. 1024 bytes) of data, increasing the basic error correction bit count from 24 bits to 36 bits will cause the chip area of the ECC engine to greatly increase, where the new value of chip area may reach approximately 1.5 times the original value of the chip area. Therefore, a novel method is required for enhancing the data protection performance of a memory device equipped with a Flash memory (e.g. Universal Serial Bus (USB) Mass Storage).

### SUMMARY OF THE INVENTION

It is therefore an objective of the claimed invention to provide a method for enhancing data protection performance, and to an associated personal computer and a storage medium storing an associated driver, in order to solve the above-mentioned problems.

It is another objective of the claimed invention to provide a method for enhancing data protection performance, and to an associated personal computer and a storage medium storing an associated driver, in order to enhance the data protection performance of a memory device equipped with a Flash memory (e.g. Universal Serial Bus (USB) Mass Storage).

It is another objective of the claimed invention to provide a method for enhancing data protection performance, and to an associated personal computer and a storage medium storing an associated driver, in order to replace/extend the data protection function of a memory device equipped with a Flash memory (e.g. USB Mass Storage).

According to a preferred embodiment of the claimed invention, a method for enhancing data protection performance is provided. The method is applied to a personal computer, the personal computer comprises/is electrically connected to a memory device, and the memory device comprises a Flash memory. The method comprises: with regard to data to be written/programmed into the Flash memory of the memory device by the personal computer, generating at least one Error Correction Code (ECC) corresponding to the data, and storing the ECC into a file within the personal computer, wherein the file is stored in a storage of the personal computer; and when it is detected that an uncorrectable error of at least one portion of the data stored in the Flash memory occurs, performing error correction according to the ECC stored in the file, in order to correct the data stored in the Flash memory.

While the method mentioned above is disclosed, an associated personal computer is further provided. The personal computer comprises a storage medium storing a driver for enhancing data protection performance, the personal computer comprises/is electrically connected to a memory device, and the memory device comprises a Flash memory, wherein when the driver is executed by the personal computer, the personal computer operates according to a method comprising: with regard to data to be written/programmed into the Flash memory of the memory device by the personal computer, generating at least one ECC corresponding to the data, and storing the ECC into a file within the personal computer, wherein the file is stored in a storage of the personal computer; and when it is detected that an uncorrectable error of at least one portion of the data stored in the Flash memory occurs, performing error correction according to the ECC stored in the file, in order to correct the data stored in the Flash memory.

While the method mentioned above is disclosed, a storage medium is provided accordingly, and the storage medium stores a driver for being executed by a personal computer. The driver is utilized for enhancing data protection performance, the personal computer comprises/is electrically connected to a memory device, and the memory device comprises a Flash memory, wherein when the driver is executed by the personal computer, the personal computer operates according to a method comprising: with regard to data to be written/programmed into the Flash memory of the memory device by the personal computer, generating at least one ECC corresponding to the data, and storing the ECC into a file within the personal computer, wherein the file is stored in a storage of the personal computer; and when it is detected that an uncorrectable error of at least one portion of the data stored in the Flash memory occurs, performing error correction according to the ECC stored in the file, in order to correct the data stored in the Flash memory.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a personal computer according to a first embodiment of the present invention.

FIG. 2 is a flowchart of a method for enhancing data protection performance according to an embodiment of the present invention.

FIGS. 3A-3C respectively illustrate some implementation details of the method shown in FIG. 2 according to an embodiment of the present invention.

FIG. 4 is a diagram of a personal computer according to a second embodiment of the present invention, where the second embodiment is a variation of the first embodiment.

### DETAILED DESCRIPTION

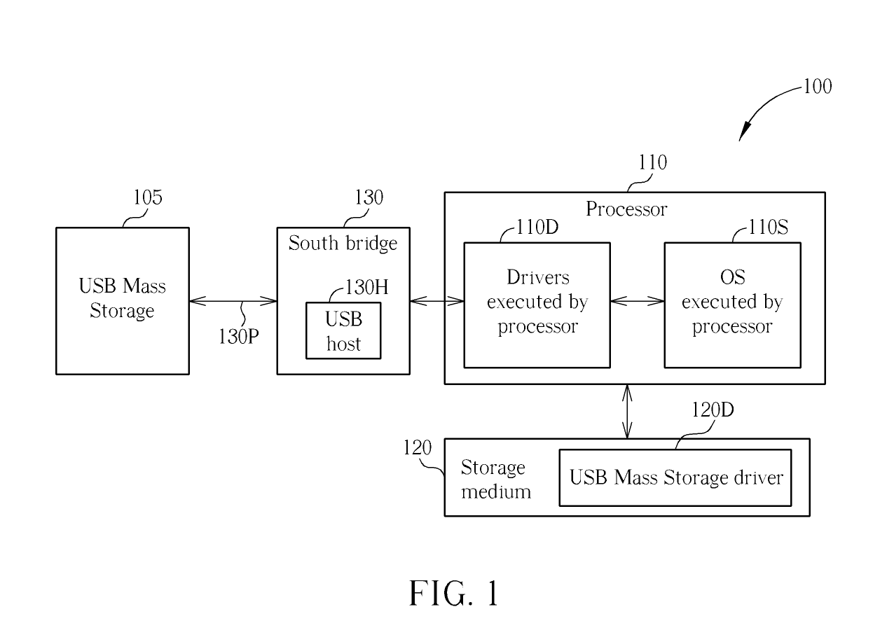

Please refer to FIG. 1, which illustrates a personal computer 100 according to a first embodiment of the present invention. For example, the personal computer 100 can be a laptop computer. In another example, the personal computer 100 can be a desktop computer. As shown in FIG. 1, the personal computer 100 comprises a processor 110, a storage medium 120, a south bridge 130 comprising at least one Universal Serial Bus (USB) host 130H, and a USB Mass Storage 105 electronically connected to a USB port 130P of the personal computer 100, where the USB Mass Storage 105 of this embodiment can be a memory device comprising a Flash memory, such as a Solid State Drive (SSD). This is for illustrative purposes only, and is not meant to be a limitation of the present invention. According to a variation of this embodiment, the USB Mass Storage can be detached from the personal computer 100, where the USB Mass Storage 105 of this variation can be a USB Flash disk comprising a Flash memory. According to other embodiments, the USB Mass Storage can be a hard disk, a compact disc drive or any other USB Mass Storage. According to another variation of this embodiment, the USB Mass Storage 105 can be electronically connected to a memory device comprising a Flash memory, in order to access the memory device. For example, the USB Mass Storage 105 of this variation can be a card reader capable of accessing a memory device comprising a Flash memory, such as a memory card complying with some standards, where examples of the memory device may include, but not limited to, memory cards complying with SD/MMC, CF, MS, or XD standards. According to other variations of this embodiment, the USB Mass Storage 105 can be replaced by a memory device that is equipped with another interface (which differs from the USB interface) and comprises a Flash memory, and the memory device is electronically connected to the personal computer 100 through the other interface such as the Peripheral Component Interconnect Express (PCI Express, PCI-E) interface.

According to this embodiment, the storage medium 120 stores at least one driver such as a USB Mass Storage driver 120D for enhancing data protection performance. Here, the notation 110D is utilized for representing the driver (or drivers) executed by the personal computer 100, and more particularly, by the processor 110, where the driver 110D may comprise one or more drivers read from the storage medium 120, such as the USB Mass Storage driver 120D read from the storage medium 120. In addition, the notation 110S is utilized for representing an operating system (OS) executed by the personal computer 100, and more particularly, by the processor 110.

According to this embodiment, the storage medium 120 represents a hard disk (HD). This is for illustrative purposes only, and is not meant to be a limitation of the present invention. According to a variation of this embodiment, the storage medium 120 represents an optical disc accessed by an optical disc drive of the personal computer 100 of this variation. For example, the optical disc can be a Compact Disc-Read Only Memory (CD-ROM) or a CD-Recordable (CD-R). In another example, the optical disc can be a Digital Versatile Disc (DVD) such as a DVD-ROM, a DVD-Recordable (DVD-R) disc, or a DVD+R disc.

According to another variation of this embodiment, the storage medium 120 represents a non-volatile (NV) memory. For example, the storage medium 120 can be a Basic Input Output System (BIOS) ROM. According to another variation of this embodiment, the storage medium 120 represents a non-volatile (NV) memory accessed by an associated interface circuit of the personal computer 100 of this variation. For example, the interface circuit is an SDD, and the storage medium 120 is a Flash memory of the SDD. According to another variation of this embodiment, the aforementioned at least one driver such as the USB Mass Storage driver 120D can be stored in a storage medium of a portable storage device such as a memory card or a USB Flash disk, where the storage medium of this variation is a Flash memory.

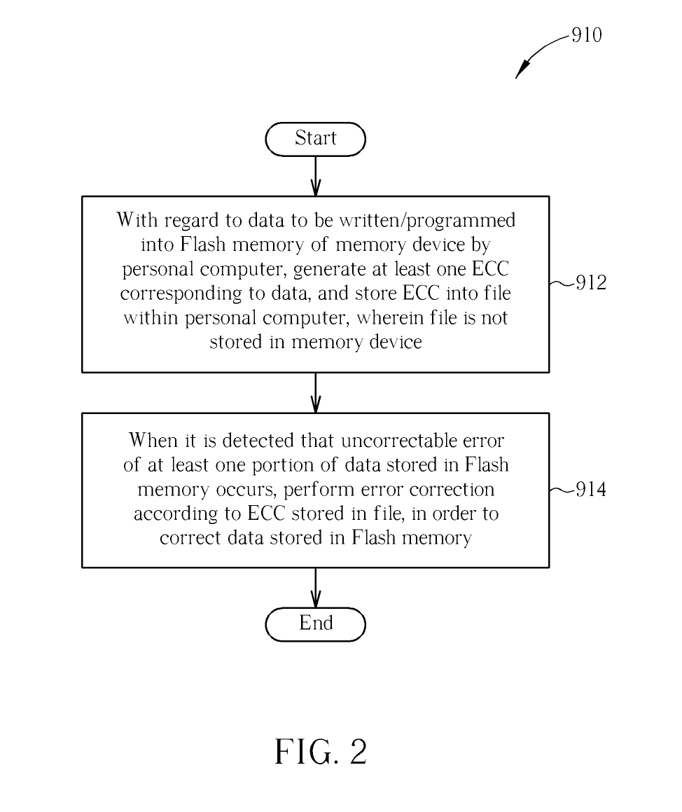

FIG. 2 is a flowchart of a method 910 for enhancing data protection performance according to an embodiment of the present invention. The method 910 can be applied to a personal computer that comprises/is electrically connected to a memory device, such as the personal computer 100 shown in FIG. 1, where the memory device comprises at least one Flash memory, and can be the memory device disclosed in any of the first embodiment and the variations thereof. For example, the personal computer may access the memory device through the USB Mass Storage 105. In another example, the memory device can be the USB Mass Storage 105. In addition, the method 910 shown in FIG. 2 can be implemented by utilizing the personal computer 100 shown in FIG. 1. More particularly, when the aforementioned at least one driver such as the USB Mass Storage driver 120D is executed by the personal computer 100, the personal computer 100 operates according to the method 910 shown in FIG. 2, where the method 910 is described as follows.

In Step 912, with regard to data to be written/programmed into the Flash memory of the memory device by the personal computer 100 (and more particularly, user data), the driver 110D executed by the processor 110 (e.g. the aforementioned at least one driver such as the USB Mass Storage driver 120D executed by the processor 110) generates at least one Error Correction Code (ECC) corresponding to the data, and stores the ECC into a file within the personal computer 100, where the file is stored in a storage of the personal computer 100, such as the storage medium 120 or another storage medium of the personal computer 100, and examples of the storage may include, but not limited to, an HD. Please note that the storage mentioned above is not the memory device. That is, in Step 912, the file is not stored in the memory device. In practice, the ECC may comprise at least one parity code. According to different variations of this embodiment, the ECC can be implemented by utilizing various kinds of encoding methods.

In Step 914, when it is detected that an uncorrectable error of at least one portion of the data stored in the Flash memory occurs, the driver 110D executed by the processor 110 performs error correction according to the ECC stored in the file, in order to correct the data stored in the Flash memory. More particularly, in a situation where the personal computer 100 reads the data stored in the Flash memory of the memory device, when it is detected that the uncorrectable error of the aforementioned at least one portion of the data stored in the Flash memory occurs, the driver 110D executed by the processor 110 performs error correction according to the ECC stored in the file, in order to reply an OS of the personal computer 100, such as the OS 110S disclosed above, with corrected data.

In practice, the driver 110D executed by the processor 110 can detect whether delay of a response of the memory device reaches a predetermined time (e.g. one second, a fixed value that is greater than one second, or a fixed value that is less than one second), in order to determine whether the uncorrectable error of the aforementioned at least one portion of the data stored in the Flash memory occurs. This is for illustrative purposes only, and is not meant to be a limitation of the present invention. According to a variation of this embodiment, the memory device can send predetermined notification information to notify the personal computer 100 of whether the uncorrectable error occurs, allowing the driver 110D executed by the processor 110 to determine whether the uncorrectable error of the aforementioned at least one portion of the data stored in the Flash memory occurs by detecting the predetermined notification information.

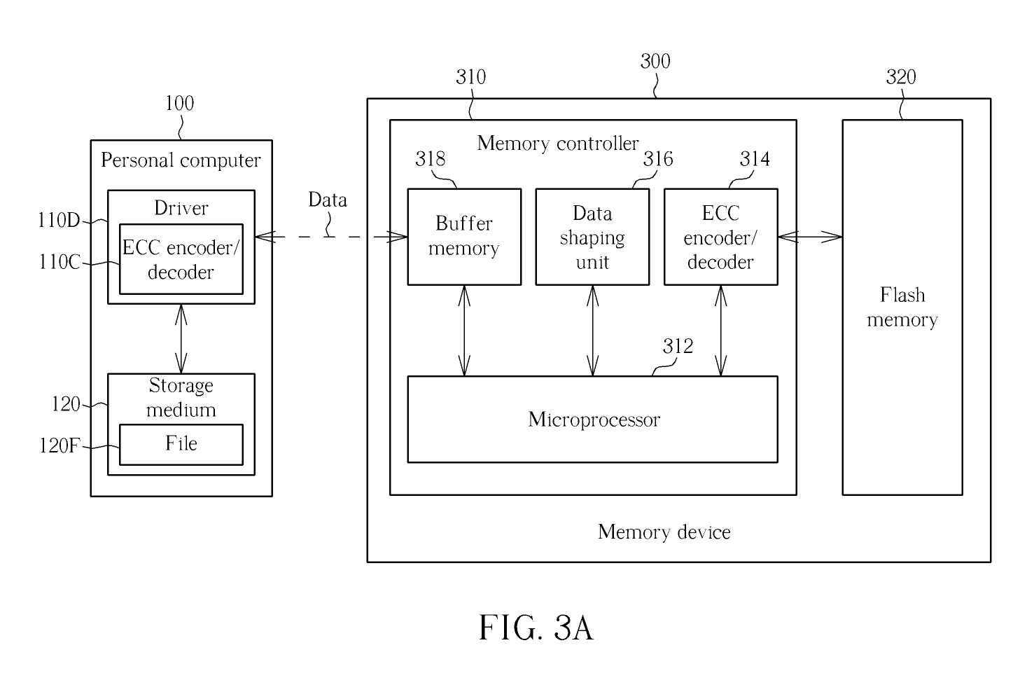

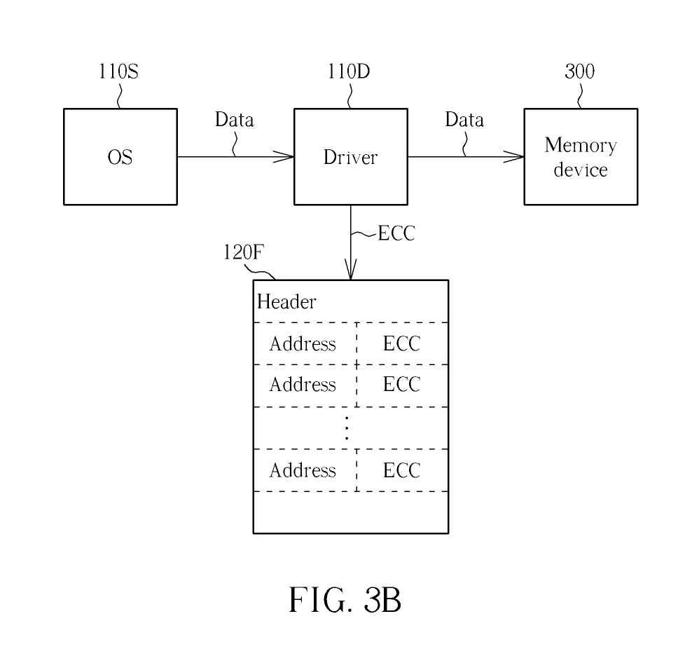

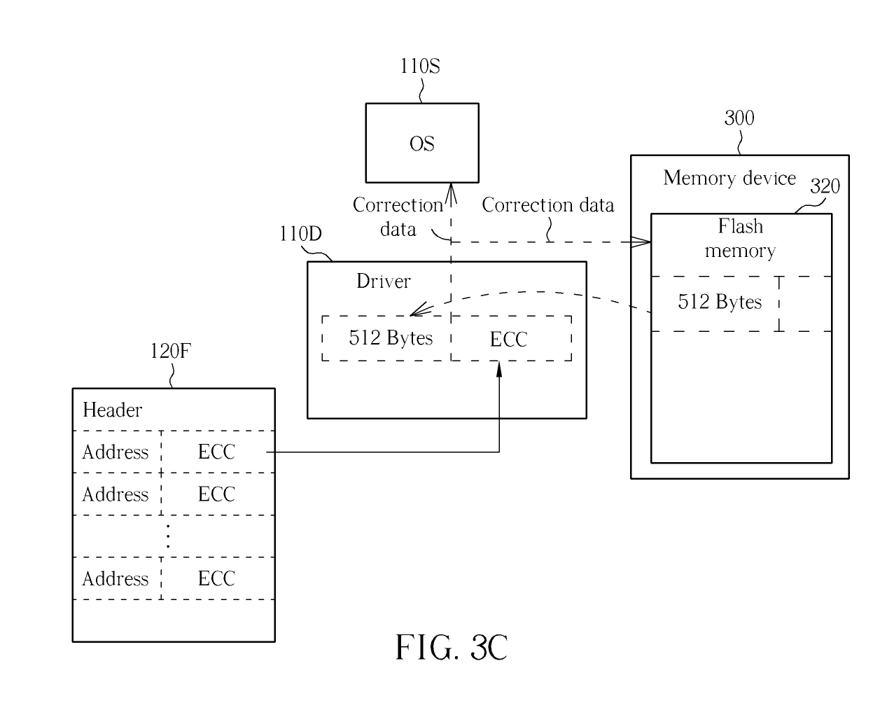

FIGS. 3A-3C respectively illustrate some implementation details of the method 910 shown in FIG. 2 according to an embodiment of the present invention. In this embodiment, the file mentioned in Step 912 can be the file 120F shown in the lower left corner of FIG. 3A, where the file 120F can be stored in the storage medium 120 mentioned above. In addition, the memory device mentioned in Step 912 can be the memory device 300 shown in the right half of FIG. 3A. For example, the memory device 300 of this embodiment can be the SSD mentioned above. This is for illustrative purposes only, and is not meant to be a limitation of the present invention. According to a variation of this embodiment, the memory device 300 can be electronically connected to the personal computer 100 through an interface device. For example, the memory device 300 of this variation can be the aforementioned memory card complying with some standards (e.g. SD/MMC, CF, MS, or XD standards), where the interface device can be the card reader mentioned above. According to other variations of this embodiment, the memory device 300 can be the aforementioned memory device that is equipped with the other interface and comprises the Flash memory, where the memory device 300 is electronically connected to the personal computer 100 through the other interface such as the PCI-E interface.

As shown in FIG. 3A, the memory device 300 comprises the memory controller 310 and the Flash memory 320, where the memory controller 310 comprises the microprocessor 312, the ECC encoder/decoder 314 (which can also be referred to as the ECC coder 314, for simplicity), the data shaping unit 316, and the buffer memory 318. The Flash memory 320 is utilized for storing information, and the memory controller 310 is utilized for controlling operations of the memory device 300. More particularly, the memory controller 310 that executes at least one program code by utilizing the microprocessor 312 can control operations of the memory device 300 according to the program code, and can utilize the ECC encoder/decoder 314, the data shaping unit 316, and the buffer memory 318 to perform ECC encoding/decoding (or ECC coding), data shaping, and buffering operations, respectively.

Typically, the basic error correction bit count (which typically represents the error correction capability measured in bits with respect to a specific amount of data) of an ECC engine of the controller within the memory device mentioned in Step 912 is less than the basic error correction bit count with which the ECC mentioned above provides the data. In this embodiment, the ECC engine is the ECC encoder/decoder 314 shown in FIG. 3A. In addition, at least one portion (e.g. a portion or all) of the driver 110D executed by the processor 110 is equivalent to an ECC encoder/decoder, which is illustrated as the ECC encoder/decoder 110C (which can also be referred to as the ECC coder 110C, for simplicity) shown in FIG. 3A in this embodiment. Thus, in comparison with the aforementioned ECC engine such as the ECC encoder/decoder 314, the driver 110D can provide better data protection performance. Therefore, by utilizing the method 910 shown in FIG. 2, the driver 110D can enhance data protection performance.

As shown in FIG. 3B, in a situation where the personal computer 100 performs writing/programming on the Flash memory 320 within the memory device 300, the OS 110S executed by the processor 110 sends the data mentioned in Step 912 to the driver 110D, and the driver 110D executed by the processor 110 sends the data to the memory device 300, and generates the ECC corresponding to the data and stores the ECC into the file 120F. According to this embodiment, the file 120F comprises a header, and further comprises one or more sets of addresses and ECCs, where the ECC in any set of the one or more sets of addresses and ECCs can be generated by utilizing the operation disclosed in Step 912, and the address of the same set is the address of the data under consideration. In practice, the header mentioned above may comprise a reference table, and the contents of the reference table can be utilized for indicating whether the ECCs corresponding to the respective addresses exist within the file 120F, respectively. In addition, the header mentioned above may further comprise related information of the one or more sets of addresses and ECCs, such as the current number of sets. This is for illustrative purposes only, and is not meant to be a limitation of the present invention. According to a variation of this embodiment, it is unnecessary that the file 120F comprises the header mentioned above. According to another variation of this embodiment, it is unnecessary that the file 120F comprises the addresses mentioned above.

As shown in FIG. 3C, in a situation where the personal computer 100 reads the data stored in the Flash memory 320 within the memory device 300, when it is detected that an uncorrectable error of at least one portion of the data stored in the Flash memory 320, such as 512 bytes of data (labeled “512 Bytes” in the right half of FIG. 3C, and simply referred to as the 512 bytes hereafter), occurs, the driver 110D executed by the processor 110 reads the corresponding ECC (i.e. the ECC corresponding to the aforementioned at least one portion of the data, such as the ECC corresponding to the 512 bytes) from the file 120F, and performs error correction on the 512 bytes read from the Flash memory 320 according to the corresponding ECC, in order to generate correction data and utilize the correction data as the corrected data mentioned in Step 914. In addition, the driver 110D executed by the processor 110 can send the correction data to the memory device 300 to correct the 512 bytes of data in the Flash memory 320. Additionally, the driver 110D executed by the processor 110 can send the correction data to the OS 110S, and more particularly, reply the OS 110S mentioned above with the correction data, so the personal computer 100 may complete the reading operation.

Please note that, for better comprehension, the 512 bytes read from the Flash memory 320 and the corresponding ECC are illustrated in the driver 110D shown in FIG. 3C, which means the driver 110D executed by the processor 110 performs processing on the 512 bytes read from the Flash memory 320 and the corresponding ECC. Typically, the 512 bytes read from the Flash memory 320 and the corresponding ECC can temporarily be stored in a certain or some memories of the personal computer 100.

According to some variations of this embodiment, in a situation where the memory device 300 is a detachable memory device (e.g. the aforementioned USB Flash disk, or the aforementioned memory card complying with some standards), when it is detected that the user is going to detach the memory device 300 from the personal computer 100, the driver 110D executed by the processor 110 can store the file 120F into the Flash memory 320 within the memory device 300, for being copied/implanted to another personal computer further. According to some variations of this embodiment, in a situation where the memory device 300 is a detachable memory device, when it is detected that the user is going to detach the memory device 300 from the personal computer 100, the driver 110D executed by the processor 110 can keep the file 120F in the storage of the personal computer 100. According to some variations of this embodiment, in a situation where the memory device 300 is a detachable memory device, when it is detected that the user is going to detach the memory device 300 from the personal computer 100, the driver 110D executed by the processor 110 can remove the file 120F from the personal computer 100. Similar descriptions are not repeated in detail for these variations.

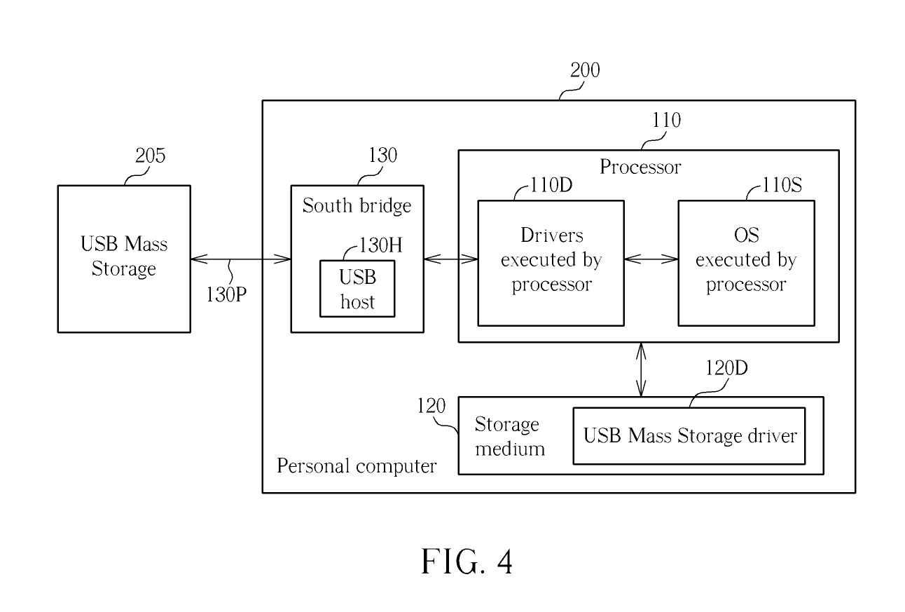

FIG. 4 is a diagram of a personal computer 200 according to a second embodiment of the present invention, where the second embodiment is a variation of the first embodiment.

Here, the aforementioned USB Mass Storage 105 is replaced by another USB Mass Storage 205 that is positioned outside the personal computer 200, where the user can detach the USB Mass Storage 205 from the USB port 130P of the personal computer 200 when needed. Similar descriptions are not repeated in detail for this embodiment.

It is an advantage of the present invention that, in comparison with the ECC engine in the aforementioned memory device, the present invention method and both the personal computer and the associated driver implemented according to the present invention can provide better data protection performance. Therefore, in contrast to the related art, the present invention can greatly enhance data protection performance. In addition, in contrast to the related art, in a situation where the chip area of the memory device mentioned above and the associated costs are not increased, the present invention can achieve the goal of enhancing data protection performance with regard to data in the memory device.

Those skilled in the art will readily observe that numerous modifications and alterations of the device and method may be made while retaining the teachings of the invention.

What is claimed is:

1. A method for enhancing data protection performance, the method being applied to a personal computer, the personal computer comprising/being electrically connected to a memory device, the memory device comprising a Flash memory, the method comprising:
with regard to data to be written/programmed into the Flash memory of the memory device by the personal computer, generating at least one Error Correction Code (ECC) corresponding to the data, and storing the ECC into a file within the personal computer, wherein the file is stored in a storage of the personal computer; and
when it is detected that an uncorrectable error of at least one portion of the data stored in the Flash memory occurs, performing error correction according to the ECC stored in the file, in order to correct the data stored in the Flash memory.

2. The method of claim 1, wherein a basic error correction bit count of an ECC engine of a controller within the memory device is less than a basic error correction bit count with which the ECC provides the data.

3. The method of claim 1, wherein the ECC comprises at least one parity code.

4. The method of claim 1, wherein the step of performing the error correction according to the ECC stored in the file in order to correct the data stored in the Flash memory further comprises:
in a situation where the personal computer reads the data stored in the Flash memory of the memory device, when it is detected that the uncorrectable error of the at least one portion of the data stored in the Flash memory occurs, performing error correction according to the ECC stored in the file, in order to reply an operating system (OS) of the personal computer with corrected data.

5. The method of claim 1, further comprising:
detecting whether delay of a response of the memory device reaches a predetermined time, in order to determine whether the uncorrectable error of the at least one portion of the data stored in the Flash memory occurs.

6. The method of claim 1, further comprising:
when it is detected that a user is going to detach the memory device from the personal computer, storing the file into the Flash memory within the memory device, for being copied/implanted to another personal computer.

7. The method of claim 1, further comprising:
when it is detected that a user is going to detach the memory device from the personal computer, keeping the file in the storage of the personal computer.

8. A personal computer, the personal computer comprising a storage medium storing a driver for enhancing data protection performance, the personal computer comprising/being electrically connected to a memory device, the memory device comprising a Flash memory, wherein when the driver is executed by the personal computer, the personal computer operates according to a method comprising:
with regard to data to be written/programmed into the Flash memory of the memory device by the personal computer, generating at least one Error Correction Code (ECC) corresponding to the data, and storing the ECC into a file within the personal computer, wherein the file is stored in a storage of the personal computer; and
when it is detected that an uncorrectable error of at least one portion of the data stored in the Flash memory occurs, performing error correction according to the ECC stored in the file, in order to correct the data stored in the Flash memory.

9. The personal computer of claim 8, wherein a basic error correction bit count of an ECC engine of a controller within the memory device is less than a basic error correction bit count with which the ECC provides the data.

10. The personal computer of claim 8, wherein the step of performing the error correction according to the ECC stored in the file in order to correct the data stored in the Flash memory further comprises:
in a situation where the personal computer reads the data stored in the Flash memory of the memory device, when it is detected that the uncorrectable error of the at least one portion of the data stored in the Flash memory occurs, performing error correction according to the ECC stored in the file, in order to reply an operating system (OS) of the personal computer with corrected data.

11. The personal computer of claim 8, wherein the method further comprises:
detecting whether delay of a response of the memory device reaches a predetermined time, in order to determine whether the uncorrectable error of the at least one portion of the data stored in the Flash memory occurs.

12. The personal computer of claim 8, wherein the method further comprises:
when it is detected that a user is going to detach the memory device from the personal computer, storing the file into the Flash memory within the memory device, for being copied/implanted to another personal computer.

13. The personal computer of claim 8, wherein the method further comprises:
when it is detected that a user is going to detach the memory device from the personal computer, keeping the file in the storage of the personal computer.

14. A storage medium, the storage medium storing a driver for being executed by a personal computer, the driver being utilized for enhancing data protection performance, the personal computer comprising/being electrically connected to a memory device, the memory device comprising a Flash memory, wherein when the driver is executed by the personal computer, the personal computer operates according to a method comprising:
with regard to data to be written/programmed into the Flash memory of the memory device by the personal computer, generating at least one ECC corresponding to the data, and storing the ECC into a file within the personal computer, wherein the file is stored in a storage of the personal computer; and
when it is detected that an uncorrectable error of at least one portion of the data stored in the Flash memory occurs, performing error correction according to the ECC stored in the file, in order to correct the data stored in the Flash memory.

15. The storage medium of claim 14, wherein a basic error correction bit count of an ECC engine of a controller within the memory device is less than a basic error correction bit count with which the ECC provides the data.

16. The storage medium of claim 14, wherein the ECC comprises at least one parity code.

17. The storage medium of claim 14, wherein the step of performing the error correction according to the ECC stored in the file in order to correct the data stored in the Flash memory further comprises:
in a situation where the personal computer reads the data stored in the Flash memory of the memory device, when it is detected that the uncorrectable error of the at least one portion of the data stored in the Flash memory occurs, performing error correction according to the ECC stored in the file, in order to reply an operating system (OS) of the personal computer with corrected data.

18. The storage medium of claim 14, wherein the method further comprises:
detecting whether delay of a response of the memory device reaches a predetermined time, in order to determine whether the uncorrectable error of the at least one portion of the data stored in the Flash memory occurs.

19. The storage medium of claim 14, wherein the method further comprises:
when it is detected that a user is going to detach the memory device from the personal computer, storing the file into the Flash memory within the memory device, for being copied/implanted to another personal computer.

20. The storage medium of claim 14, wherein the method further comprises:
when it is detected that a user is going to detach the memory device from the personal computer, keeping the file in the storage of the personal computer.
